(19) United States
(12) Patent Application Publication
(10) Pub. No.: US 2009/0020885 A1
(43) Pub. Date: Jan. 22, 2009

(54) Semiconductor device and method of manufacturing the same

(76) Inventor: Masanori Onodera, Tokyo (JP)

Correspondence Address: SPANSION LLC C/O MURABITO , HAO & BARNES LLP, TWO NORTH MARKET STREET, THRID FLOOR, SAN JOSE, CA, 95113, US

(21) Appl. No.: 12/005,870

(22) Filed: Dec. 28, 2007

(30) Foreign Application Priority Data
Dec. 28, 2006 (JP) JP2006-355025

(51) Int. Cl. H01L 23/52; H04B 1/38; G06F 12/02

(52) U.S. Cl. 257/777; 455/73; 711/103; 257/E23.141; 711/E12.008

(57) ABSTRACT

One embodiment in accordance with the invention can include a semiconductor device that includes a first substrate, a projection portion that has a first semiconductor chip mounted on the first substrate, a second substrate that is provided on the first substrate and is electrically coupled to the first substrate, and a second semiconductor chip that is mounted on the second substrate. An opening portion is formed by the second substrate. The projection portion is arranged in the opening portion.

### CLAIM OF PRIORITY

This patent application claims the benefit and priority of the co-pending Japanese Patent Application No. JP2006-355025, filed on Dec. 28, 2006, the disclosure of which is hereby incorporated by reference.

### BACKGROUND

Recently, there is a demand for downsizing a semiconductor device that is used for a portable electronic device such as a mobile phone or a nonvolatile record media of an IC memory card. And so, there is a demand for packaging a semiconductor chip efficiently. There is a technology using a package-on-package (PoP) in which a package (built-in semiconductor device) mounting a semiconductor chip is stacked.

FIG. 1 illustrates a cross sectional view of a semiconductor device using the PoP in accordance with a conventional art. As shown in FIG. 1, a plurality of first semiconductor chips 20 are stacked on a first substrate 10 such as a glass epoxy substrate with a die attach 22. A pad electrode 24 of the first semiconductor chip 20 is electrically coupled to a pad electrode 18 of the first substrate 10 through a wire 26. The first semiconductor chip 20 is resin-sealed with a resin-sealing member 28 (a projection portion) such as an epoxy resin. A land electrode 16 is provided on a face mounting the first semiconductor chip 20 of the first substrate 10. A solder ball 34 is for coupling the first substrate 10 and a second substrate 30a and is provided on the land electrode 16. A land electrode 12 is provided on a face of the first substrate 10 on an opposite side of the face mounting the first semiconductor chip 20. A solder ball 14 is provided on the land electrode 12. There is a wire for coupling the pad electrode 18 and a coupling portion coupling the land electrode 16 and the land electrode 12 on the first substrate 10.

The second substrate 30a such as a glass epoxy substrate is provided on the first semiconductor chip 20 side of the first substrate 10. A land electrode 32 is provided on the first substrate 10 side of the second substrate 30a. The second substrate 30a is electrically coupled to the first substrate 10 through the solder ball 34 provided on the land electrode 32. A plurality of second semiconductor chips 40 are stacked on the second substrate 30a on an opposite side of the first substrate 10 through a die attach 42. A pad electrode 44 of the second semiconductor chip 40 is electrically coupled to a pad electrode 36 of the second substrate 30a through a wire 46. The second semiconductor chip 40 is resin-sealed with a resin-sealing member 48 such as an epoxy resin. There is a wire for coupling the pad electrode 36 and a coupling portion coupling the pad electrode 36 and the land electrode 32 on the second substrate 30a.

FIG. 2 illustrates a cross sectional view of a semiconductor device using the PoP in accordance with a conventional art. As shown in FIG. 2, an upper face of the resin-sealing member 28 is fixed to the second substrate 30a with an adhesive agent 50, being different from the first conventional embodiment shown in FIG. 1. Other structures are the same as shown in FIG. 1. The same components have the same reference numerals.

FIG. 3 illustrates a cross sectional view of a semiconductor device using the PoP in accordance with a conventional art. As shown in FIG. 3, a first semiconductor chip 60 is not stacked and is flip-chip mounted (face-down mounted) on a pad electrode 17 of the first substrate 10 through a bump 62, being different from that shown in FIG. 1. There is provided an underfill member 64 composed of an epoxy resin between the first substrate 10 and the first semiconductor chip 60. Other structures are the same as that shown in FIG. 1. The same components have the same reference numerals.

Japanese Patent Application Publication No. 2003-133521 (hereinafter referred to as Document 1) discloses a technology where an opening portion is formed on a substrate, a support tape is provided on a face of the opening portion of the substrate, and a semiconductor chip is mounted on the support tape so as to be in the opening portion. Japanese Patent Application Publication No. 2003-7972 discloses a technology where there is provided an intermediate substrate having an opening portion on which a semiconductor chip mounted on a substrate is arranged between stacked substrates.

It is possible to downsize the semiconductor device in accordance with FIGS. 1-3 with the technology disclosed in Document 1. However, the manufacturing cost is increased because the semiconductor chip is mounted on the support tape in the technology disclosed in Document 1.

### SUMMARY

Various embodiments in accordance with the present invention can provide a semiconductor device that may reduce the manufacturing cost and also be downsized. and a method of manufacturing the semiconductor device, but is not limited to such.

According to an embodiment of the present invention, there is provided (or produced) a semiconductor device that can include, but is not limited to, a first substrate, a projection portion that has a first semiconductor chip mounted on the first substrate, a second substrate that is provided on the first substrate and is electrically coupled to the first substrate, and a second semiconductor chip that is mounted on the second substrate. An opening portion is formed on a center portion of the second substrate. And the projection portion is arranged in the opening portion. In accordance with an embodiment of the present invention, it is possible to reduce the manufacturing cost and downsize the semiconductor device.

Note that the second substrate may have a region on which the second semiconductor chip is mounted. And that region may cover the opening portion. With this structure, it is possible to improve the resistance to an impact when the surround of the second semiconductor chip is mounted on the second substrate entirely.

In one embodiment, the second semiconductor chip may have an electrode coupled to the second substrate. And the electrode may be arranged directly on the second substrate, but is not limited to such. With this structure, it is possible to conduct heat or an ultra sonic wave provided to the second substrate to the electrode efficiently during a wire bonding. It is therefore possible to maintain a fair quality rate during the wire bonding.

In one embodiment, the semiconductor may have a fixing portion that affixes an upper face of the projection portion to a bottom face of the second semiconductor chip. With this structure, it is possible to protect the second semiconductor chip at bottom that can be easily damaged when the semiconductor device is subjected to mechanical impact.

In one embodiment, the opening portion may be filled with the fixing portion. With this structure, the fixing portion may cover the opening portion under the second semiconductor chip at the bottom entirely. It is therefore possible to improve resistance to a mechanical stress of the second semiconductor chip to a large extent.

In one embodiment, the fixing portion may include adhesive agent that includes silicone. With this structure, it is possible to release thermal stress between the second semiconductor chip and the resin-sealing member.

In one embodiment, the projection portion may have a resin-sealing member that seals the first semiconductor chip. The first semiconductor chip may be face-down and mounted on the first substrate. And the projection portion may be the first semiconductor chip. With this structure, it is possible to downsize the semiconductor device, even if the first semiconductor chip is face-down mounted and the thickness of the first semiconductor chip increases.

In one embodiment, the first semiconductor chip may have a plurality of semiconductor chips that are stacked. With this structure, it is possible to downsize the semiconductor device even if the first semiconductor chips are stacked.

In one embodiment, the semiconductor device may have a terminal coupling that couples the first substrate and the second substrate. With this structure, it is possible to reduce an interval between the coupling terminals in a lateral direction because an interval between the first substrate and the second substrate is reduced.

According to one embodiment of the present invention, a method of manufacturing a semiconductor device can include, but is not limited to, mounting a first semiconductor chip on a first substrate, mounting a second semiconductor chip on a second substrate having an opening portion, coupling the first substrate and the second substrate so that a projection portion having the first semiconductor chip is arranged in the opening portion of the second substrate. In accordance with an embodiment of the present invention, it is possible to reduce the manufacturing cost and downsize the semiconductor device.

### BRIEF DESCRIPTION OF THE DRAWINGS

FIG. 1 illustrates a cross sectional view of a semiconductor device in accordance with a conventional art;

FIG. 2 illustrates a cross sectional view of a semiconductor device in accordance with a conventional art;

FIG. 3 illustrates a cross sectional view of a semiconductor device in accordance with a conventional art;

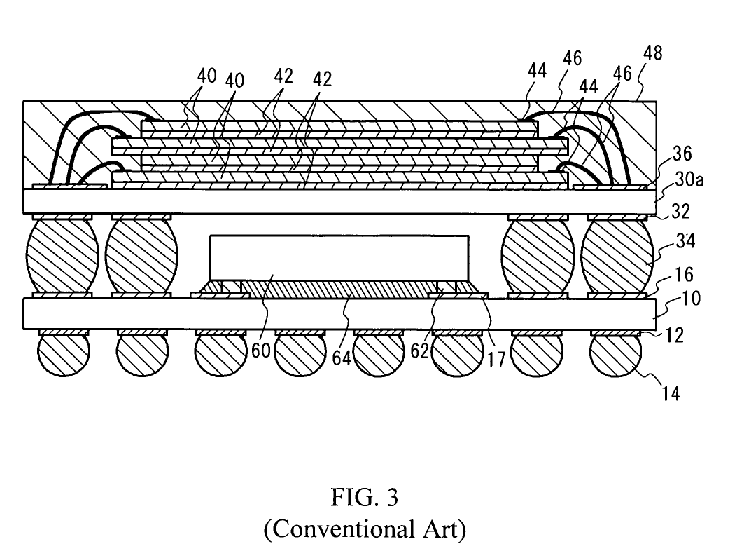

FIG. 4 illustrates a cross sectional view of a semiconductor device in accordance with an embodiment of the invention;

FIG. 5 illustrates a top view of a second substrate of the semiconductor device in accordance with an embodiment of the invention;

FIG. 6 illustrates a cross sectional view accounting for a manufacturing method of the semiconductor device in accordance with an embodiment of the invention;

FIG. 7 illustrates a cross sectional view accounting for the manufacturing method of the semiconductor device in accordance with an embodiment of the invention;

FIG. 8 illustrates a cross sectional view of a semiconductor device in accordance with an embodiment of the invention;

FIG. 9 illustrates a cross sectional view of a semiconductor device in accordance with an embodiment of the invention;

FIG. 10 illustrates a cross sectional view of a semiconductor device in accordance with an embodiment of the invention;

FIG. 11 illustrates a cross sectional view of a semiconductor device in accordance with an embodiment of the invention; and

FIG. 12 illustrates a cross sectional view of a semiconductor device in accordance with an embodiment of the invention.

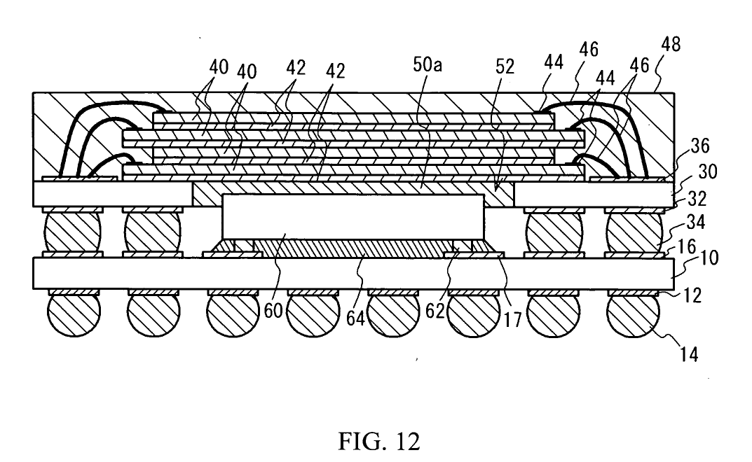

FIG. 13 illustrates a block diagram of an exemplary portable phone, upon which various embodiments of the invention may be implemented.

FIG. 14 illustrates a block diagram of an exemplary computing device, upon which various embodiments of the invention may be implemented.

FIG. 15 illustrates an exemplary portable multimedia device, or media player, in accordance with various embodiments of the invention.

### DETAILED DESCRIPTION

Reference will now be made in detail to various embodiments in accordance with the invention, examples of which are illustrated in the accompanying drawings. While the invention will be described in conjunction with various embodiments, it will be understood that these various embodiments are not intended to limit the invention. On the contrary, the invention is intended to cover alternatives, modifications and equivalents, which may be included within the scope of the invention as construed according to the Claims. Furthermore, in the following detailed description of various embodiments in accordance with the invention, numerous specific details are set forth in order to provide a thorough understanding of the invention. However, it will be evident to one of ordinary skill in the art that the invention may be practiced without these specific details. In other instances, well known methods, procedures, components, and circuits have not been described in detail as not to unnecessarily obscure aspects of the invention.

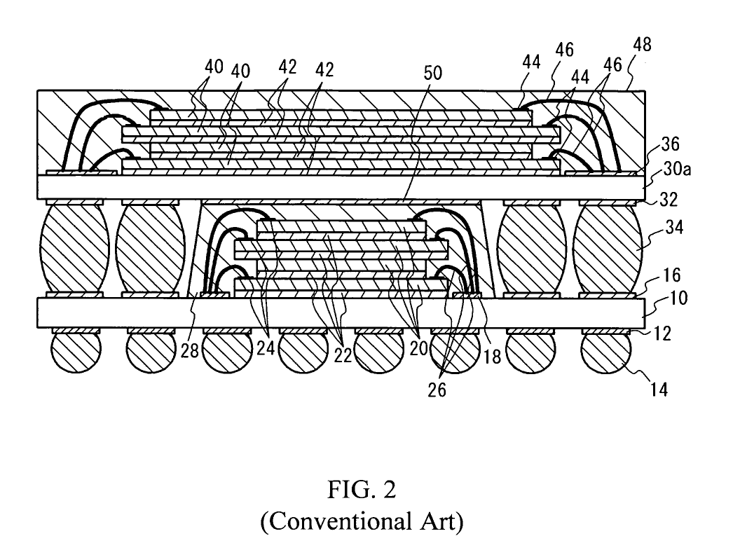

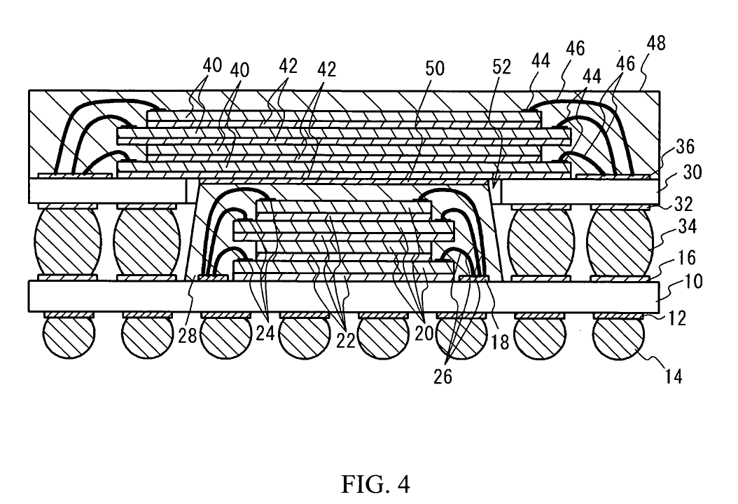

FIG. 4 illustrates a cross sectional view of a semiconductor device in accordance with an embodiment of the invention. For example, a projection portion having the first semiconductor chip corresponds to the resin-sealing member 28, and the upper face of the resin-sealing member 28 is fixed to a back face of the second semiconductor chip 40 with the adhesive agent 50. As shown in FIG. 4, an opening portion 52 is formed by a second substrate 30 and the resin-sealing member 28 (the projection portion) having the first semiconductor chip 20 is arranged in the opening portion 52, being different from the second conventional embodiment shown in FIG. 2. The upper face of the resin-sealing member 28 acting as the projection portion is fixed to the bottom face of the second semiconductor chip with the die attach 42 and the adhesive agent 50. Other structures are similar to that shown in FIG. 2. Note that similar components have the same reference numerals in order to avoid a duplicated explanation.

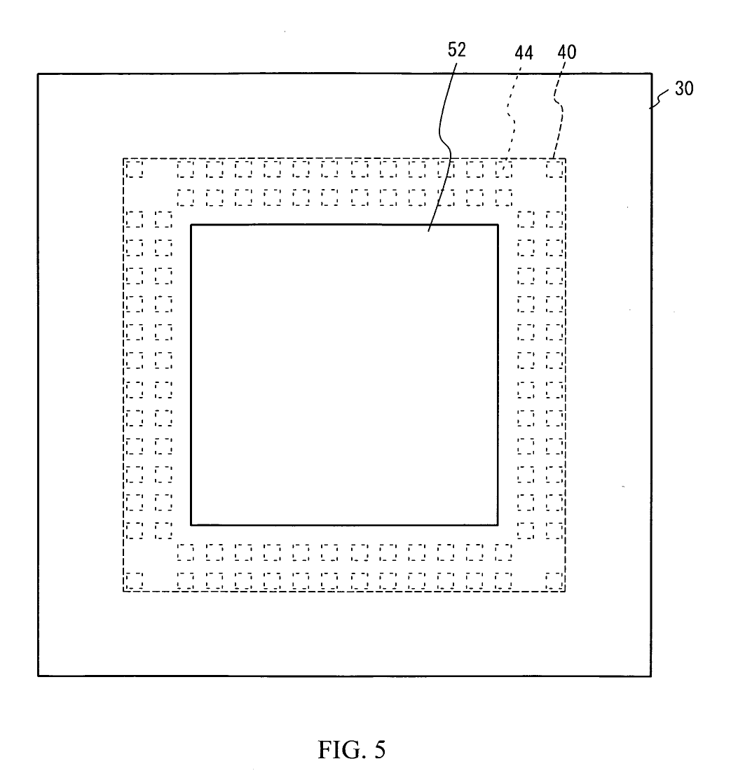

FIG. 5 illustrates a top view of a second substrate of the semiconductor device in accordance with an embodiment of the invention. Specifically, FIG. 5 illustrates a top view showing a positional relationship between the opening portion 52 formed by the second substrate 30, the second semiconductor chip 40 and the pad electrode 44 of the second semiconductor chip 40. The second semiconductor chip 40 is formed so as to cover the opening portion 52. That is, the opening portion 52 is included in a region of the second substrate 30 mounting the second semiconductor chip 40. And, the pad electrode 44 to be electrically coupled to the second substrate 30 is provided directly on the second substrate 30. That is, the opening portion 52 of the second substrate 30 does not include a region of the upper face of the second substrate 30 on which the pad electrode 44 is projected.

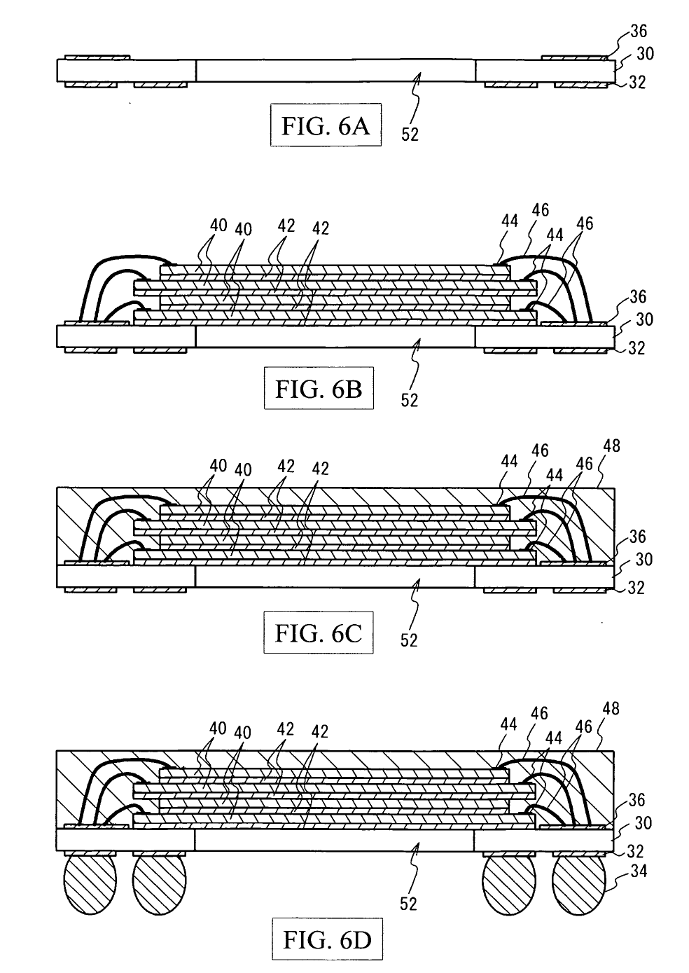

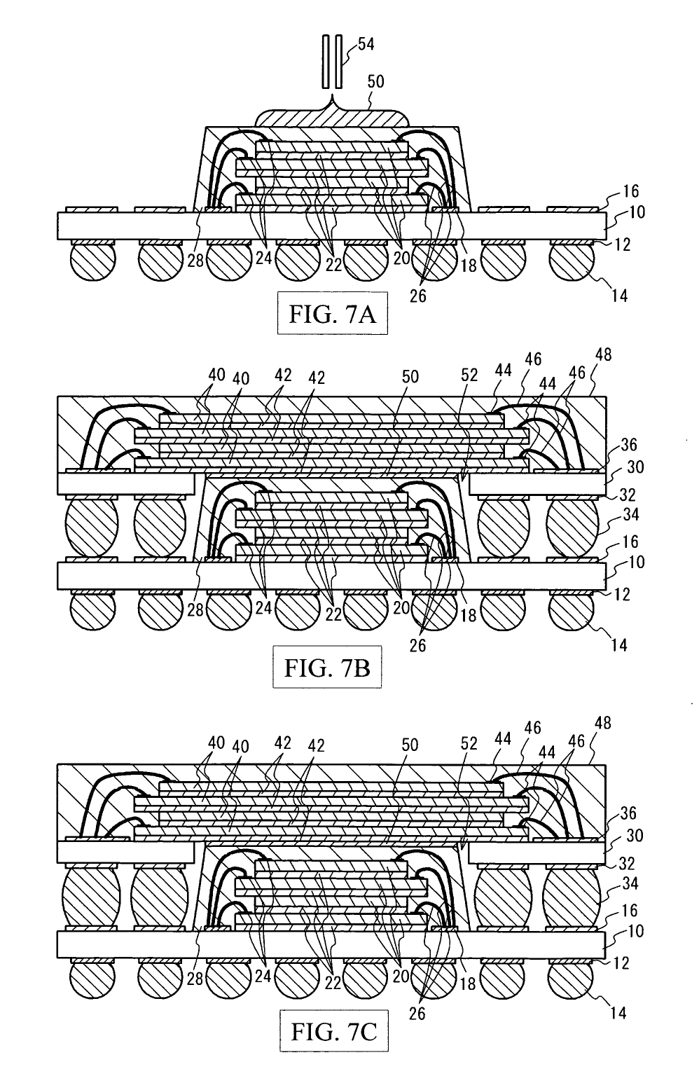

A description will be given of an exemplary method of manufacturing a semiconductor device in accordance with an embodiment, with reference to FIG. 6A through FIG. 7C. As shown in FIG. 6A, the land electrode 32 and the pad electrode 36 composed of a metal such as gold or copper are formed on the second substrate 30, which forms the opening portion 52 on the center portion thereof. The second substrate 30, for example, has a thickness of 300 μm, but is not limited to such.

As shown in FIG. 6B, the second semiconductor chip 40 is mounted on the second substrate 30 with the die attach 42 such as a die attach film composed of polyimid resin. Further, a plurality of the second semiconductor chips 40 are stacked and mounted with the die attach 42. The pad electrode 44 of the second semiconductor chip 40 is coupled to the pad electrode 36 of the second substrate 30 with the metal wire 46.

As shown in FIG. 6C, the second semiconductor chip 40 is sealed with the resin-sealing member 48 composed of an epoxy resin. As shown in FIG. 6D, the solder ball 34 is formed on the land electrode 32 of the second substrate 30.

As shown in FIG. 7A, a plurality of the first semiconductor chips 20 are stacked and mounted on the first substrate 10. The first semiconductor chip 20 is sealed with the resin-sealing member 28 composed of an epoxy resin or the like. Thus, the resin-sealing member 28 acting as the projection portion having the first semiconductor chip 20 is formed. The solder ball 14 is formed on the land electrode 12 of the first substrate 10. The silicone-based adhesive agent 50 is provided on the upper face of the resin-sealing member 28 with a dispenser 54.

As shown in FIG. 7B, the resin-sealing member 28 acting as the projection portion is arranged in the opening portion 52 formed by the second substrate 30. As shown in FIG. 7C, the first substrate 10 is electrically coupled to the second substrate 30 with the solder ball 34 when the solder ball 34 is reflowed. And, the second semiconductor chip 40 is mechanically connected and fixed to the resin-sealing member 28 with the die attach 42 and the adhesive agent 50. In this manner, a semiconductor device in accordance with an embodiment can be fabricated.

In accordance with an embodiment, the resin-sealing member 28 is arranged in the opening portion 52. It is possible to reduce the height of the semiconductor device by arranging the projecting resin-sealing member 28 in the opening portion 52. In one embodiment, it is possible to reduce the height of the semiconductor device by approximately 250 μm compared to a conventional art, in a case where the thickness of the second substrate 30 is approximately 300 μm and the thickness of the adhesive agent 50 is approximately 50 μm. Further, it is possible to downsize the semiconductor device in a lateral direction because the solder ball 34 may be downsized. It is possible to decrease the manufacturing cost because the second semiconductor chip 40 is mounted on the second substrate 30 and the support tape disclosed in Document 1 is not necessary. Further, it is possible to improve resistance to impact.

And, as shown in FIG. 5, the second semiconductor chip 40 is mounted on the second substrate 30 so as to cover the opening portion 52. That is, a region of the second substrate 30 mounting the second semiconductor chip 40 covers the opening portion 52 of the second substrate 30. In one embodiment, it is therefore possible to improve the resistance to impact when the surround of the second semiconductor chip 40 is held entirely by the second substrate 30. Further, the second semiconductor chip 40 has the pad electrode 44 to be coupled to the second substrate 30 and is arranged directly on the second substrate 30. It is therefore possible to conduct a heat or an ultra sonic wave given to the second substrate 30 to the pad electrode 44 efficiently, when the wire 46 is formed in a case where the opening portion 52 is formed on (or by) the second substrate 30. It is therefore possible to maintain a fair quality rate during the wire bonding of the wire 46.

Further, as shown in FIG. 4, the upper face of the resin-sealing member 28 is fixed to the bottom face of the second semiconductor chip 40 with the die attach 42 and the adhesive agent 50 acting as the fixing portion. Thus, the upper face of the resin-sealing member 28 protects the second semiconductor chip 40 at the bottom. It is therefore possible to protect the second semiconductor chip 40 at the bottom that is easy to be damaged, in a case where the semiconductor device is subjected to mechanical impact. Particularly in a case where the thickness of the second semiconductor chip 40 is less than 100 μm, the second semiconductor chip 40 can be easily damaged when subjected to mechanical impact. In one embodiment, it is therefore effective to fix the upper face of the resin-sealing member 28 to the bottom face of the second semiconductor chip 40 as shown herein.

In one embodiment, the adhesive agent 50 is an elastic adhesive agent including silicone. The fixing portion includes an elastic adhesive agent including silicone. There is little alteration in the elastic adhesive agent including silicone at a temperature where the solder melts. The second semiconductor chip 40 and the resin-sealing member 28 are subjected to a thermal stress caused by a temperature change. It is however possible to reduce the stress when the elastic adhesive agent including silicone is used as the adhesive agent 50. And, it is possible to release the heat generated on the second semiconductor chip 40 effectively because the elastic adhesive agent including silicone has an advantage in heat conductivity.

Further, the semiconductor device includes the stacked first semiconductor chips 20. The first substrate 10 and the second substrate 30 get higher and the semiconductor device is upsized, when the first semiconductor chips 20 are stacked. It is however possible to downsize the semiconductor device effectively, according to an embodiment. It is possible to downsize the semiconductor device when the number of the first semiconductor chip 20 is one.

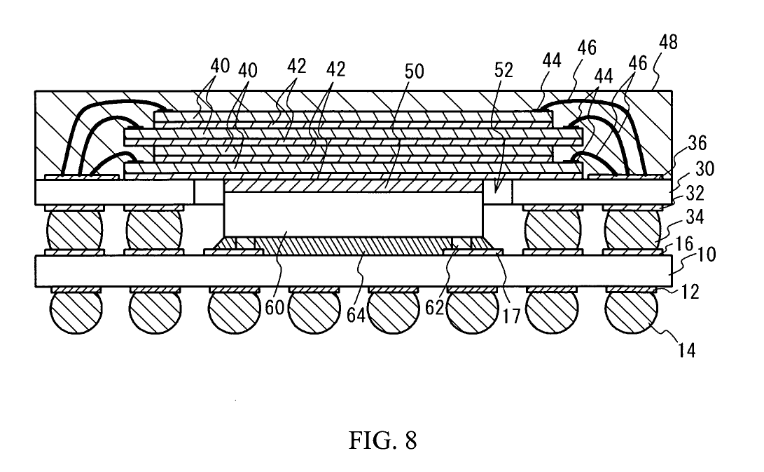

One embodiment can include a case of a semiconductor device in which the projection portion including the first semiconductor chip 60 is face-down mounted. The upper face of the first semiconductor chip 60, a face of the first semiconductor chip 60 having no circuit, is fixed to the back face of the second semiconductor chip 40 with the adhesive agent 50. As shown in FIG. 8, the first semiconductor chip 20 is flip-chip (face-down) mounted on the pad electrode 17 of the first substrate 10 with the bump 62. There is provided the underfill member 64 composed of an epoxy resin between the first substrate 10 and the first semiconductor chip 60. Other structures can be similar to those described herein. The same components have the same reference numerals in order to avoid a duplicated explanation.

The first semiconductor chip 60 may be face-down mounted on the first substrate 10. And the first semiconductor chip 60 may be arranged in the opening portion 52 formed by substrate 30. The thickness of the first semiconductor chip 60 is approximately 150 μm and larger than a case where the first semiconductor chip 60 is face-up mounted, in a case where the first semiconductor chip 60 is face-down mounted. It is however possible to downsize the semiconductor device effectively, in accordance with an embodiment.

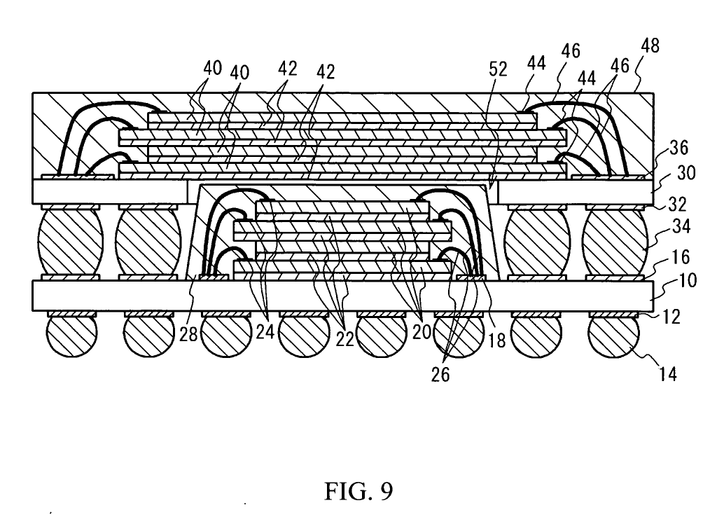

In one embodiment, the projection portion including the first semiconductor chip acts as the resin-sealing member 28, and the upper face of the resin-sealing member 28 is not fixed to the back face of the second semiconductor chip 40. As shown in FIG. 9, the upper face of the resin-sealing member 28 is not fixed to the back face of the second semiconductor chip 40. That is, the second semiconductor chip 40 is separated from the resin-sealing member 28 at an interval. Other structures can be similar to those described herein. The same components have the same reference numerals in order to avoid a duplicated explanation.

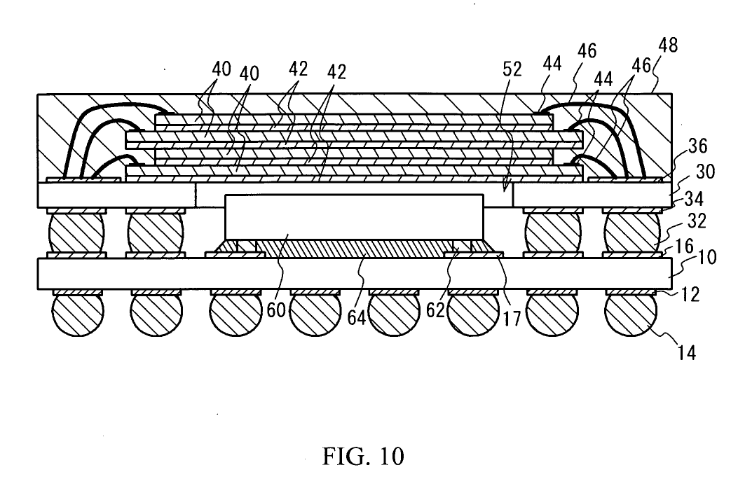

One embodiment can include a case of a semiconductor device in which the projection portion including the first semiconductor chip 60 is face-down mounted and the upper face of the first semiconductor chip 60 is not fixed to the back face of the second semiconductor chip 40. As shown in FIG. 10, the upper face of the first semiconductor chip 60 is not fixed to the back face of the second semiconductor chip 40. That is, the second semiconductor chip 40 is separated from the first semiconductor chip 20 at an interval. Other structures can be similar to those described herein. The same components have the same reference numerals in order to avoid a duplicated explanation.

In accordance with various embodiments described herein, it is possible to reduce the manufacturing cost because the resin-sealing member 28 or the upper face of the first semiconductor chip 60 is not fixed to the bottom face of the second semiconductor chip 40, although the mechanical strength of the semiconductor device can be reduced because the second semiconductor chip 40 at the bottom is not protected by the resin-sealing member 28 or the first semiconductor chip 60.

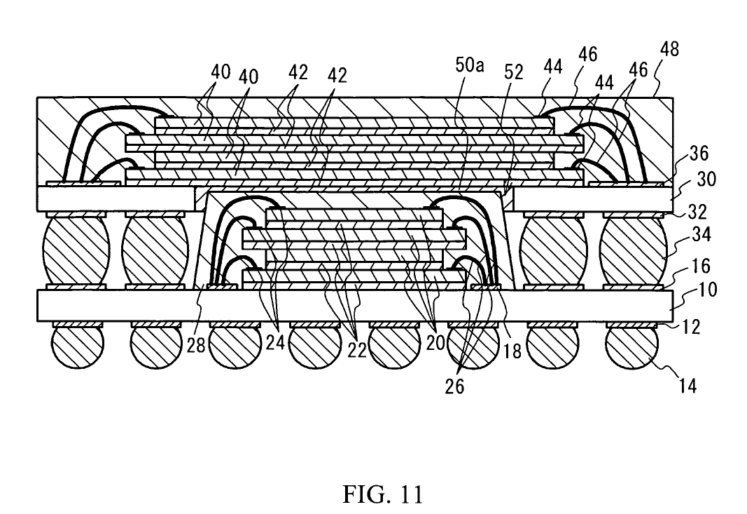

One embodiment can include a case of a semiconductor device in which the projection portion including the first semiconductor chip acts as the resin-sealing member 28 and the opening portion 52 is filled with an adhesive agent 50a. As shown in FIG. 11, the opening portion 52 is filled with the adhesive agent 50a. In other words, there is provided the adhesive agent 50a between the side face of the resin-sealing member 28 acting as the projection portion and the side face of the opening portion 52. Other structures can be similar to those described herein. The same components have the same reference numerals in order to avoid a duplicated explanation.

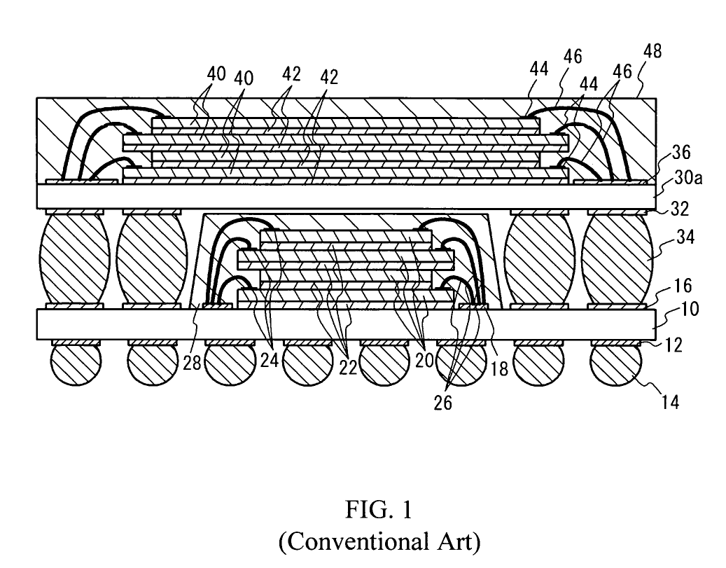

One embodiment can include a case of a semiconductor device in which the projection portion including the first semiconductor chip 60 is face-down mounted and the opening portion 52 is filled with the adhesive agent 50a. As shown in FIG. 1, the opening portion 52 is filled with the adhesive agent 50a. Other structures can be similar to those described herein. The same components have the same reference numerals in order to avoid a duplicated explanation.

In accordance with various embodiments described herein, the fixing portion including the adhesive agent 50 may cover the opening portion 52 under the second semiconductor chip 40 at the bottom entirely. It is therefore possible to improve the resistance to mechanical stress of the second semiconductor chip 40 by a large extent. It is further possible to improve the resistance to dropping of the semiconductor device by a large extent, because a contact area is increased between an upper package and a lower package. Therefore, the semiconductor device in accordance with embodiments herein has an advantage as an electronic device that is desirable for resistance to dropping in particular.

In accordance with various embodiments, there is the solder ball (coupling terminal) coupling the first substrate 10 and the second substrate 30. The solder may be composed of lead-tin (PbSn) solder, lead-free solder such as SnAgCu, tin-zinc (SnZn) solder or the like. A bump composed of a metal such as Au or Cu may be used instead of the solder. The coupling terminal may be a projecting conductor coupling the first substrate 10 and the second substrate 30 electrically. In accordance with an embodiment of the present invention, it is possible to reduce the interval between the coupling terminals in a lateral direction and downsize the semiconductor device, because it is possible to reduce the interval between the first substrate 10 and the second substrate 30.

The second semiconductor chip 40 may be face-down mounted on the second substrate 30, although the second semiconductor chip 40 is face-up mounted on the second substrate 30 in the above description. The projection portion may be a resin-sealing member sealing the first semiconductor chip 60 that is face-down mounted, although the resin-sealing member 28 or the face-down mounted first semiconductor chip 60 acts as the projection portion. The projection portion may have the first semiconductor chip and project from the first substrate. The fixing portion may fix the projection portion to the second semiconductor chip, although the die attach 42 and the adhesive agent 50 act as the fixing portion.

It is noted that the various embodiments of the invention described herein are applicable to flash memory and devices that utilize flash memory. Flash memory is a form of non-volatile memory that can be electrically erased and reprogrammed. As such, flash memory, in general, is a type of electrically erasable programmable read only memory (EEPROM).

Like Electrically Erasable Programmable Read Only Memory (EEPROM), flash memory is nonvolatile and thus can maintain its contents even without power. However, flash memory is not standard EEPROM. Standard EEPROMs are differentiated from flash memory because they can be erased and reprogrammed on an individual byte or word basis while flash memory can be programmed on a byte or word basis, but is generally erased on a block basis. Although standard EEPROMs may appear to be more versatile, their functionality requires two transistors to hold one bit of data. In contrast, flash memory requires only one transistor to hold one bit of data, which results in a lower cost per bit. As flash memory costs far less than EEPROM, it has become the dominant technology wherever a significant amount of non-volatile, solid-state storage is needed.

Exemplary applications of flash memory include digital audio players, digital cameras, digital video recorders, and mobile phones. Flash memory is also used in USB flash drives, which are used for general storage and transfer of data between computers. Also, flash memory is gaining popularity in the gaming market, where low-cost fast-loading memory in the order of a few hundred megabytes is required, such as in game cartridges. Additionally, flash memory is applicable to cellular handsets, smartphones, personal digital assistants, set-top boxes, digital video recorders, networking and telecommunication equipments, printers, computer peripherals, automotive navigation devices, and gaming systems.

As flash memory is a type of non-volatile memory, it does not need power to maintain the information stored in the chip. In addition, flash memory offers fast read access times and better shock resistance than traditional hard disks. These characteristics explain the popularity of flash memory for applications such as storage on battery-powered devices (e.g., cellular phones, mobile phones, IP phones, wireless phones, etc.).

Flash memory stores information in an array of floating gate transistors, called “cells”, each of which traditionally stores one bit of information. However, newer flash memory devices, such as MirrorBit® Flash Technology from Spansion Inc., can store more than 1 bit per cell. The MirrorBit cell doubles the intrinsic density of a Flash memory array by storing two physically distinct bits on opposite sides of a memory cell. Each bit serves as a binary bit of data (e.g., either 1 or 0) that is mapped directly to the memory array. Reading or programming one side of a memory cell occurs independently of whatever data is stored on the opposite side of the cell.

With regards to wireless markets, flash memory that utilizes MirrorBit® technology has several key advantages. For example, flash memory that utilizes MirrorBit® technology is capable of burst-mode access as fast as 80 MHz, page access times as fast as 25 ns, simultaneous read-write operation for combined code and data storage, and low standby power (e.g., 1 μA).

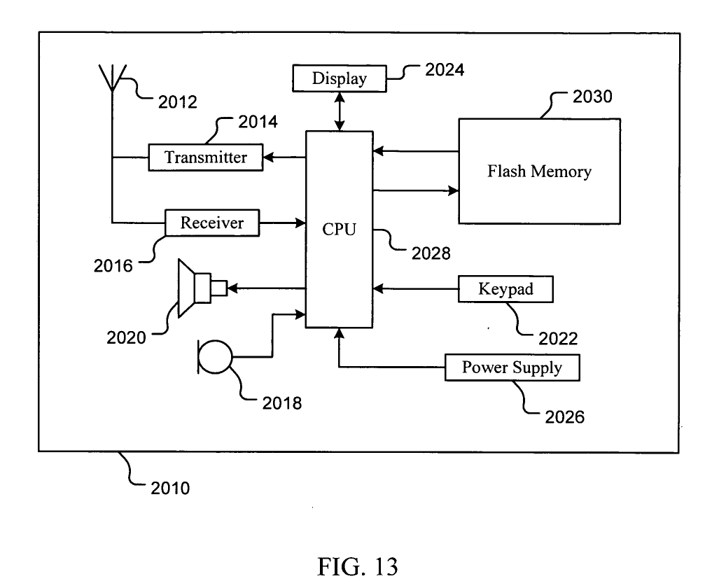

FIG. 13 shows a block diagram of an exemplary portable telephone 2010 (e.g., cell phone, cellular phone, mobile phone, internet protocol phone, wireless phone, etc.), upon which various embodiments of the invention can be implemented. The cell phone 2010 can include, but is not limited to, an antenna 2012 coupled to a transmitter 2014 and a receiver 2016, as well as a microphone 2018, a speaker 2020, a keypad 2022, and a display 2024. The cell phone 2010 can also include, but is not limited to, a power supply 2026 and a central processing unit (CPU) 2028, which may be an embedded controller, conventional microprocessor, or the like. In addition, the cell phone 2010 can include integrated, flash memory 2030. Flash memory 2030 can be implemented in a wide variety of ways. For example, flash memory 2030 can be implemented in any manner similar to that described herein, but is not limited to such. For example in an embodiment, flash memory 2030 can be implemented in a manner similar to any semiconductor device described herein, but is not limited to such. An embodiment of the invention also provides a method of manufacturing flash memory 2030. In various embodiments, the flash memory 2030 can be utilized with various devices, such as mobile phones, cellular phones, internet protocol phones, and/or wireless phones.

Flash memory 2030 can be implemented in two primary varieties, NOR-type flash and NAND-type flash. While the general memory storage transistor can be the same for all flash memory, it is the interconnection of the memory cells that differentiates the designs. In a conventional NOR-type flash memory, the memory cell transistors are coupled to the bit lines in a parallel configuration, while in a conventional NAND-type flash memory, the memory cell transistors are coupled to the bit lines in series. For this reason, NOR-type flash is sometimes referred to as “parallel flash” and NAND-type flash is referred to as “serial flash.”

Traditionally, portable phone (e.g., cell phone) CPUs have needed only a small amount of integrated NOR-type flash memory to operate. However, as portable phones (e.g., cell phone) have become more complex, offering more features and more services (e.g., voice service, text messaging, camera, ring tones, email, multimedia, mobile TV, MP3, location, productivity software, multiplayer games, calendar, and maps), flash memory requirements have steadily increased. Thus, an improved flash memory will render a portable phone more competitive in the telecommunications market.

Also, as mentioned above, flash memory 2030 is applicable to a variety of devices other than portable phones. For instance, flash memory 2030 can be utilized in personal digital assistants, set-top boxes, digital video recorders, networking and telecommunication equipments, printers, computer peripherals, automotive navigation devices, and gaming systems, but is not limited to such.

It is noted that the components (e.g., 2012, 2014, 2016, 2022, 2028, 2030, etc.) of portable telephone 2010 can be coupled to each other in a wide variety of ways. For example, in an embodiment, the antenna 2012 can be coupled to transmitter 2014 and receiver 2016. Additionally, the transmitter 2014, receiver 2016, speaker 2020, microphone 2018, power supply 2026, keypad 2022, flash memory 2030 and display 2024 can each be coupled to the processor (CPU) 2028. It is pointed out that in various embodiments, the components of portable telephone 2010 can be coupled to each other via, but are not limited to, one or more communication buses, one or more data buses, one or more wireless communication technologies, one or more wired communication technologies, or any combination thereof.

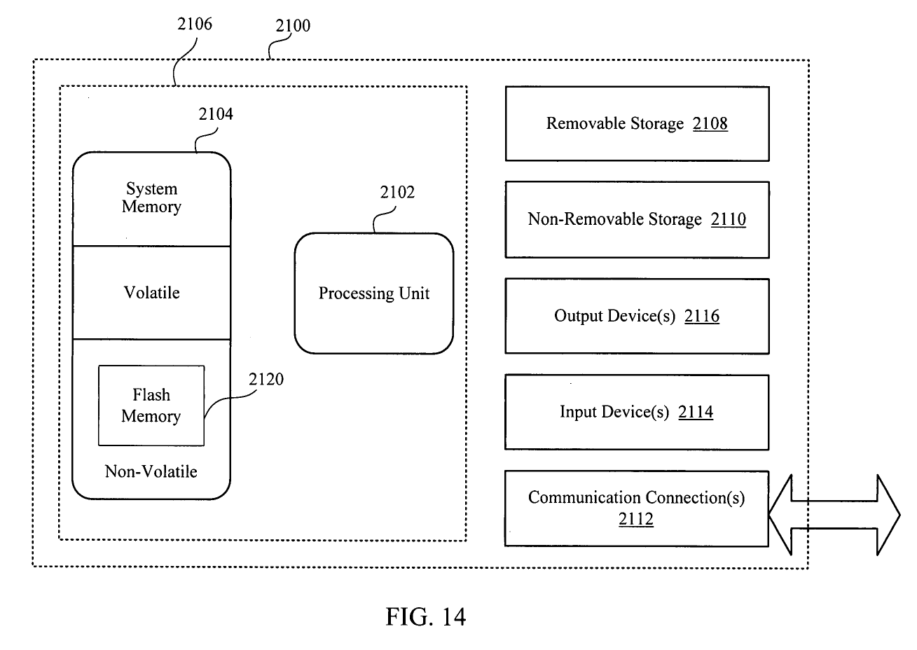

FIG. 14 illustrates a block diagram of an exemplary computing device 2100, upon which various embodiments of the invention can be implemented. Although computing device 2100 is shown and described in FIG. 14 as having certain numbers and types of elements, the embodiments are not necessarily limited to the exemplary implementation. That is, computing device 2100 can include elements other than those shown, and can include more elements than the elements that are shown. For example, computing device 2100 can include a greater number of processing units than the one (processing unit 2102) shown. In an embodiment, computing device 2100 can include additional components not shown in FIG. 14.

Also, it is appreciated that the computing device 2100 can be a variety of things. For example, computing device 2100 may be, but is not limited to, a personal desktop computer, a portable notebook computer, a personal digital assistant (PDA), and a gaming system. Flash memory 2120 is especially useful with small-form-factor computing devices such as PDAs and portable gaming devices. Flash memory 2120 offers several advantages. In one example, flash memory 2120 is able to offer fast read access times while at the same time being able to withstand shocks and bumps better than standard hard disks. This can be desirable as small computing devices are often moved around and encounter frequent physical impacts. Also, flash memory 2120 is more able than other types of memory to withstand intense physical pressure and/or heat. Thus, portable computing devices are able to be used in a greater range of environmental variables.

Computing device 2100 can include at least one processing unit 2102 and memory 2104. Depending on the exact configuration and type of computing device, memory 2104 may be volatile (such as RAM), non-volatile (such as ROM, flash memory 2120, etc.) or some combination of the two. This most basic configuration of computing device 2100 is illustrated in FIG. 14 by line 2106. Additionally, device 2100 may also have additional features/functionality. For example, device 2100 may also include additional storage (removable and/or non-removable) including, but not limited to, magnetic or optical disks or tape. In one example, in the context of a gaming system, the removable storage could a game cartridge receiving component utilized to receive different game cartridges. In another example, in the context of a Digital Versatile Disc (DVD) recorder, the removable storage is a DVD receiving component utilized to receive and read DVDs. Such additional storage is illustrated in FIG. 14 by removable storage 2108 and non-removable storage 2110. Computer storage media includes volatile and nonvolatile, removable and non-removable media implemented in any method or technology for storage of information such as computer readable instructions, data structures, program modules or other data. Memory 2104, removable storage 2108 and non-removable storage 2110 are all examples of computer storage media. Computer storage media includes, but is not limited to, RAM, ROM, EEPROM, flash memory 2120 or other memory technology, CD-ROM, digital video disks (DVD) or other optical storage, magnetic cassettes, magnetic tape, magnetic disk storage or other magnetic storage devices, or any other medium which can be used to store the desired information and which can accessed by device 2100. Any such computer storage media may be part of device 2100.

In the present embodiment, the flash memory 2120 can be implemented in a wide variety of ways. For example, flash memory 2120 can be implemented in any manner similar to that described herein, but is not limited to such. For example in an embodiment, flash memory 2120 can be implemented in a manner similar to any semiconductor device described herein, but is not limited to such. An embodiment of the invention also provides a method of manufacturing flash memory 2120. In various embodiments, the flash memory 2120 can be utilized with various devices, such as personal digital assistants, set-top boxes, digital video recorders, networking and telecommunication equipments, printers, computer peripherals, automotive navigation devices, gaming systems, mobile phones, cellular phones, internet protocol phones, and/or wireless phones. Further, in one embodiment, the flash memory 2120 utilizes MirrorBit® technology to allow storing of two physically distinct bits on opposite sides of a memory cell.

Device 2100 may also contain communications connection(s) or coupling(s) 2112 that allow the device to communicate with other devices. Communications connection(s) 2112 is an example of communication media. Communication media typically embodies computer readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection or coupling, and wireless media such as acoustic, radio frequency (RF), infrared and other wireless media. The term computer readable media as used herein includes both storage media and communication media.

It is noted that the components (e.g., 2102, 2104, 2110, 2120, etc.) of computing device 2100 can be coupled to each other in a wide variety of ways. For example in various embodiments, the components of computing device 2100 can be coupled to each other via, but are not limited to, one or more communication buses, one or more data buses, one or more wireless communication technologies, one or more wired communication technologies, or any combination thereof.

Device 2100 may also have input device(s) 2114 such as keyboard, mouse, pen, voice input device, game input device (e.g., a joy stick, a game control pad, and/or other types of game input device), touch input device, etc. Output device(s) 2116 such as a display (e.g., a computer monitor and/or a projection system), speakers, printer, network peripherals, etc., may also be included. All these devices are well known in the art and need not be discussed at length here.

Aside from mobile phones and portable computing devices, flash memory is also widely used in portable multimedia devices, such as portable music players. As users would desire a portable multimedia device to have as large a storage capacity as possible, an increase in memory density would be advantageous.

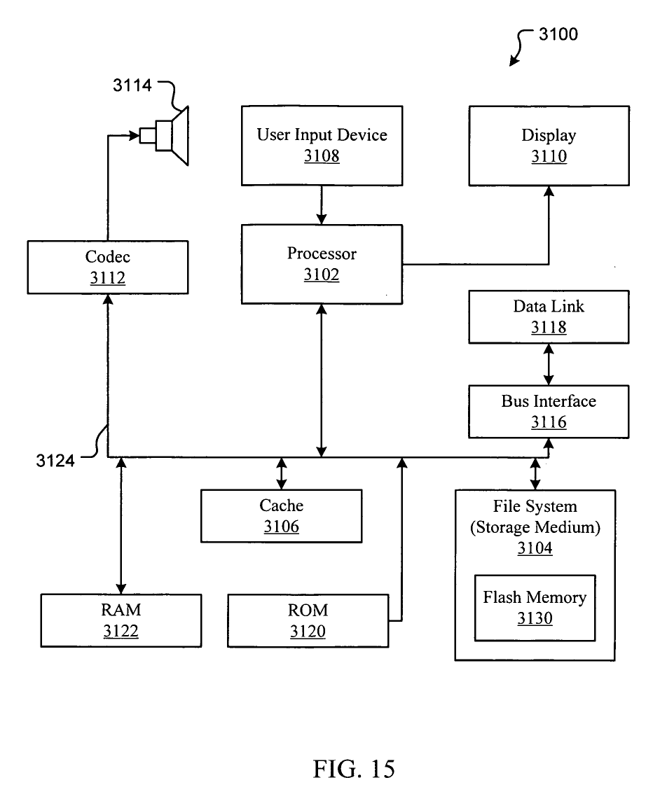

FIG. 15 shows an exemplary portable multimedia device, or media player, 3100 in accordance with an embodiment of the invention. The media player 3100 can include a processor 3102 that pertains to a microprocessor or controller for controlling the overall operation of the media player 3100. The media player 3100 can store media data pertaining to media assets in a file system 3104 and a cache 3106. The file system 3104 is, typically, a storage medium or a plurality of storage media, such as disks, memory cells, and the like. The file system 3104 typically provides high capacity storage capability for the media player 3100. Also, file system 3104 can include flash memory 3130. In the present embodiment, the flash memory 3130 can be implemented in a wide variety of ways. For example, flash memory 3130 can be implemented in any manner similar to that described herein, but is not limited to such. For example in an embodiment, flash memory 3130 can be implemented in any manner similar to any semiconductor device described herein, but is not limited to such. An embodiment of the invention also provides a method of manufacturing flash memory 3130. In various embodiments, the flash memory 3130 can be utilized with various devices, such as personal digital assistants, set-top boxes, digital video recorders, networking and telecommunication equipments, printers, computer peripherals, automotive navigation devices, gaming systems, mobile phones, cellular phones, internet protocol phones, and/or wireless phones. However, since the access time to the file system 3104 is relatively slow, the media player 3100 can also include a cache 3106. The cache 3106 is, for example, Random-Access Memory (RAM) provided by semiconductor memory. The relative access time to the cache 3106 is substantially shorter than for the file system 3104. However, the cache 3106 does not have the large storage capacity of the file system 3104. Further, the file system 3104, when active, consumes more power than does the cache 3106. The power consumption is particularly important when the media player 3100 is a portable media player that is powered by a battery (not shown). The media player 3100 also includes a RAM 3122 and a Read-Only Memory (ROM) 3120. The ROM 3120 can store programs, utilities or processes to be executed in a non-volatile manner. The RAM 3122 provides volatile data storage, such as for the cache 3106.

The media player 3100 also includes a user input device 3108 that allows a user of the media player 3100 to interact with the media player 3100. For example, the user input device 3108 can take a variety of forms, such as a button, keypad, dial, etc. Still further, the media player 3100 includes a display 3110 (screen display) that can be controlled by the processor 3102 to display information to the user. A data bus 3124 can facilitate data transfer between at least the file system 3104, the cache 3106, the processor 3102, and the CODEC 3112. The media player 3100 also includes a bus interface 3116 that couples to a data link 3118. The data link 3118 allows the media player 3100 to couple to a host computer.

In one embodiment, the media player 3100 serves to store a plurality of media assets (e.g., songs, photos, video, etc.) in the file system 3104. When a user desires to have the media player play/display a particular media item, a list of available media assets is displayed on the display 3110. Then, using the user input device 3108, a user can select one of the available media assets. The processor 3102, upon receiving a selection of a particular media item, supplies the media data (e.g., audio file, graphic file, video file, etc.) for the particular media item to a coder/decoder (CODEC) 3110. The CODEC 3110 then produces analog output signals for a speaker 3114 or a display 3110. The speaker 3114 can be a speaker internal to the media player 3100 or external to the media player 3100. For example, headphones or earphones that couple to the media player 3100 would be considered an external speaker.

In a particular embodiment, the available media assets are arranged in a hierarchical manner based upon a selected number and type of groupings appropriate to the available media assets. For example, in the case where the media player 3100 is an MP3-type media player, the available media assets take the form of MP3 files (each of which corresponds to a digitally encoded song or other audio rendition) stored at least in part in the file system 3104. The available media assets (or in this case, songs) can be grouped in any manner deemed appropriate. In one arrangement, the songs can be arranged hierarchically as a list of music genres at a first level, a list of artists associated with each genre at a second level, a list of albums for each artist listed in the second level at a third level, while at a fourth level a list of songs for each album listed in the third level, and so on.

It is noted that the components (e.g., 3102, 3104, 3120, 3130, etc.) of media player 3100 can be coupled to each other in a wide variety of ways. For example, in an embodiment, the codec 3122, RAM 3122, ROM 3120, cache 3106, processor 3102, storage medium 3104, and bus interface 3116 can be coupled to data bus 3124. Furthermore, the data link 3118 can be coupled to the bus interface 3116. The user input device 3108 and the display 3110 can be coupled to the processor 3102 while the speaker 3114 can be coupled to the codec 3112. It is pointed out that in various embodiments, the components of media player 3100 can be coupled to each other via, but are not limited to, one or more communication buses, one or more data buses, one or more wireless communication technologies, one or more wired communication technologies, or any combination thereof.

In various embodiments in accordance with the invention, it is noted that any mention of “couple”, “coupled”, and/or “coupling” may include direct and/or indirect connection between elements.

The foregoing descriptions of various specific embodiments in accordance with the invention have been presented for purposes of illustration and description. They are not intended to be exhaustive or to limit the invention to the precise forms disclosed, and obviously many modifications and variations are possible in light of the above teaching. The invention can be construed according to the Claims and their equivalents.

We claim:

1. A semiconductor device comprising:
a first substrate;
a projection portion that has a first semiconductor chip mounted on the first substrate;
a second substrate that is provided on the first substrate and is electrically coupled to the first substrate; and
a second semiconductor chip that is mounted on the second substrate,
wherein the second substrate forms an opening portion; and
the projection portion is arranged in the opening portion.

2. The semiconductor device as claimed in claim 1, wherein:
the second substrate has a region on which the second semiconductor chip is mounted; and
the region covers the opening portion.

3. The semiconductor device as claimed in claim 1, wherein:
the second semiconductor chip has an electrode to be coupled to the second substrate; and
the electrode is arranged on the second substrate.

4. The semiconductor device as claimed in claim 1 further comprising a fixing portion that affixes an upper face of the projection portion to a bottom face of the second semiconductor chip.

5. The semiconductor device as claimed in claim 4, wherein the opening portion comprises the fixing portion.

6. The semiconductor device as claimed in claim 4, wherein the fixing portion includes an adhesive agent.

7. The semiconductor device as claimed in claim 1, wherein the projection portion has a resin-sealing member.

8. The semiconductor device as claimed in claim 1, wherein:
the first semiconductor chip is face-down mounted on the first substrate; and
the projection portion is the first semiconductor chip.

9. The semiconductor device as claimed in claim 1, wherein the first semiconductor chip includes a plurality of semiconductor chips.

10. The semiconductor device as claimed in claim 1 further comprising a terminal coupling that couples the first substrate and the second substrate.

11. A wireless communications device, comprising:
a processor;
a communications component coupled to the processor;
a transmitter coupled to the processor;
a receiver;
an antenna coupled to the transmitter circuit and the receiver circuit; and
a memory coupled to the processor, the memory comprising:
a first substrate;
a projection portion that has a first semiconductor chip mounted on the first substrate;
a second substrate that is provided on the first substrate and is electrically coupled to the first substrate; and
a second semiconductor chip that is mounted on the second substrate,
wherein the second substrate forms an opening portion; and
the projection portion is arranged in the opening portion.

12. The wireless communications device of claim 11, wherein said memory is NAND flash memory.

13. The wireless communications device of claim 11, wherein said memory is NOR flash memory.

14. The wireless communications device of claim 11, wherein said memory comprises at least one memory cell operable to store more than one bit.

15. A computing device comprising:
a processor;
an input component coupled to the processor;
an output component coupled to the processor; and
a memory coupled to the processor, the memory comprising:
a first substrate;
a projection portion that has a first semiconductor chip mounted on the first substrate;
a second substrate that is provided on the first substrate and is electrically coupled to the first substrate; and
a second semiconductor chip that is mounted on the second substrate,
wherein the second substrate forms an opening portion; and
the projection portion is arranged in the opening portion.

16. The computing device of claim 15, wherein said computing device is a personal computer (PC).

17. The computing device of claim 15, wherein said computing device is a personal digital assistant (PDA).

18. The computing device of claim 15, wherein said computing device is a gaming system.

19. The computing device of claim 15, wherein said memory is NAND flash memory.

20. The computing device of claim 15, wherein said memory is NOR flash memory.
